(19) United States
(12) Patent Application Publication
(10) Pub. No.: US 2009/0174992 A1
(43) Pub. Date: Jul. 9, 2009

(54) System and Method for Supporting Electrical Connectivity Between Information Handling System Chassis Components

(76) Inventors: Eric Simon, Cedar Park, TX (US); Kevin Mundt, Austin, TX (US)

Correspondence Address: HAMILTON & TERRILE, LLP, P.O. BOX 203518, AUSTIN, TX, 78720, US

(21) Appl. No.: 11/971,324

(22) Filed: Jan. 9, 2008

(51) Int. Cl. H05K 7/02; H05K 7/04; B05D 5/12

(52) U.S. Cl. 361/679.02; 427/58

(57) ABSTRACT

An information handling system chassis having a passivated surface accepts electrical communication through a conductive ink disposed on a portion of the surface from which the passivation is removed. For example, a magnesium chassis passivated with phosphate has a portion mechanically cleaned and conductive ink placed over the cleaned portion with a pad printing process. The conductive ink provides electrical communication between the chassis and other portions of the chassis, processing component grounds and other electrical connection needs.

### BACKGROUND OF THE INVENTION

1. Field of the Invention

The present invention relates in general to the field of information handling system chassis design, and more particularly to a system and method for supporting electrical connectivity between information handling system chassis components.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems are typically built from a variety of components provided by a variety of suppliers. Generally the components are built into a chassis which serves the dual purpose of protecting the components in a solid structure and providing shielding of electromagnetic radiation produced by the components. For example, a metallic chassis provides support against physical damage that might occur to components if the chassis is dropped or bumped. A metallic chassis also creates a Faraday cage to provide effective containment of electromagnetic radiation generated within the chassis. Often, an information handling system chassis is built from a number of metallic parts that are assembled during the manufacture process. When multiple metallic parts are used to build the chassis, the separate pieces are typically electrically connected with each other in order to provide electromagnetic shielding by the assembled parts. For example, metal grounding clips are connected between different chassis parts so that electrical energy flows between the surfaces of each chassis part.

Information handling system chassis are built from a variety of metals and alloys. One metal that has gained acceptance for use in information handling system chassis is magnesium. Magnesium offers light weight and a hard surface that resists scratches and other damage, qualities that are desirable in portable information handling systems. One disadvantage with magnesium is that it tends to oxidize rapidly. To address oxidation, magnesium chassis components are typically treated prior to painting. Generally, heavy metal passivation techniques have been abandoned in favor of more environmentally techniques, such as phosphate passivation treatment. However, conventional passivation treatment techniques tend to reduce the conductive properties along the surface of the magnesium. For example, one type of passivized magnesium has resistance of approximately 410 Milliohm while unpassivized magnesium has resistance of approximately 5.3 Milliohms. In order to provide effective electromagnetic suppression, a chassis surface should have resistance of less than 30 Milliohms. Although magnesium surface conductivity may be increased by other techniques, such as chromium pickling, plating and spray-on conductive coatings, such techniques tend to be costly and environmentally unfriendly both in the application of the materials at manufacture and the recycling of materials at end of use.

### SUMMARY OF THE INVENTION

Therefore a need has arisen for a system and method which supports electrical connectivity between information handling system chassis components.

In accordance with the present invention, a system and method are provided which substantially reduce the disadvantages and problems associated with previous methods and systems for manufacture of information handling system chassis components. Conductive ink applied to a metallic chassis protects the chassis from oxidation and provides electrical communication between the chassis and other components of an information handling system, such as for a ground or for electromagnetic shielding.

More specifically, a die cast magnesium chassis portion is passivated against oxidation by a phosphate passivation technique, such as in preparation for paint. Passivation is removed at selected portions of the chassis, such as by mechanical cleaning through openings of a passivation removal template. Conductive ink is applied at the selected portions to protect the unpassivated portions from oxidation and to provide electrical communication between the chassis and another component of an information handling system, such as a processing component ground or another portion of the chassis. For example, a magnesium chassis has conductive ink, such as silver or carbon ink disposed over sections that are mechanically cleaned to allow electrical connectors to communicate electrically with the magnesium.

The present invention provides a number of important technical advantages. One example of an important technical advantage is that electrical connectivity is supported between passivated information handling system chassis parts with minimal cost and environmental impact. Conductive ink pad printing applies conductive ink using available techniques in specific locations and patterns, as opposed to entire surfaces, to provide reduced manufacturing costs and environmental impact. Having electrical connectivity with reduced resistance between information handling system chassis components improves shielding of electromagnetic radiation caused by processing components supported within the chassis.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of a portable information handling system;

FIG. 2 depicts a passivation removal template aligned with an information handling system chassis base; and

FIG. 3 depicts the information handling system chassis base with conductive ink disposed by an in pad printer.

### DETAILED DESCRIPTION

Conductive ink disposed on a passivated information handling system chassis provides electrical communication between the chassis and other parts of the information handling system for grounding and electromagnetic interference shielding. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

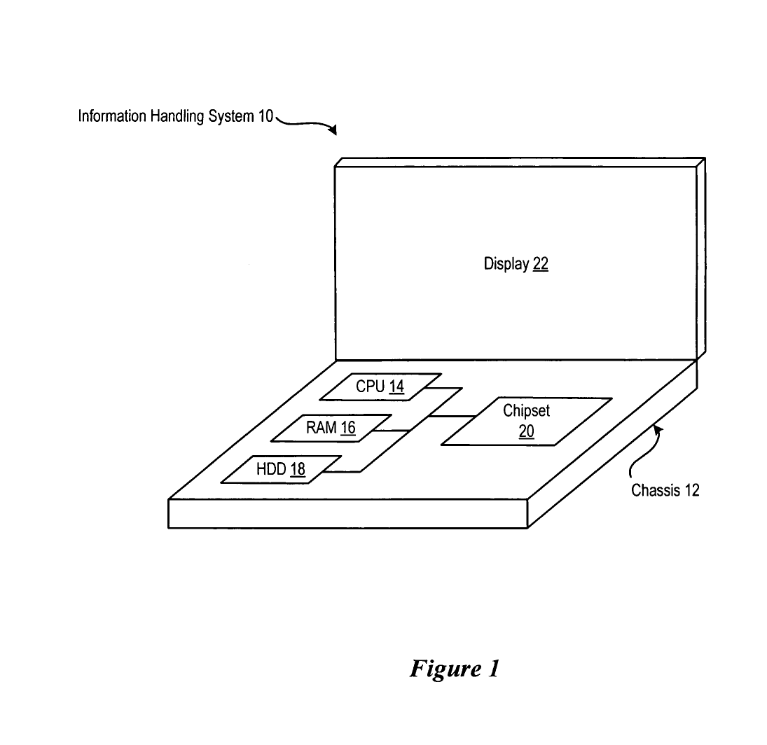

Referring now to FIG. 1, a block diagram depicts a portable information handling system 10. Information handling system 10 has a portable chassis 12 that contains a variety of processing components, such as a CPU 14, RAM 16, a hard disk drive 18 and a chipset 20. An integrated display 22 fits in a rotationally coupled lid, which rotates between an open position to allow use of the information handling system and a closed position that protects display 22 from damage. Chassis 12 is built from a metal to provide support and protection to the processing components. The metal of chassis 12 also provides a ground reference for the processing components and shielding to reduce the amount of electromagnetic energy generated by the processing components that exits the chassis. Chassis 12 may be an integral unit but generally is built from several die cast portions that are coupled to each other during manufacture of information handling system 10. For example, chassis 12 is built from die cast magnesium that is passivated, such as with a phosphate treatment, and then painted.

During manufacture of information handling system 12, chassis 12 is provided electrical communication with the processing components and between separate portions of chassis 12 by creating conductive locations on different parts of the surface of chassis 12. For example, chassis 12 needs electrical communication at one or more locations that provide a ground for processing components and that provide a coupling point for different portions of the chassis which are coupled together during manufacture, such as by screws, clips or EMI gaskets. For the most part, electrical communication with chassis 12 needs good surface conductivity at specific locations. Thus, reduced conductivity with chassis 12 caused by passivication is addressed at the specific locations where good surface conductivity is needed. To provide good conductivity, passivication at predetermined locations is removed and a conductive ink is disposed at the locations where the passivication is removed to provide good surface conductivity to chassis 12. The conductive ink seals the surface of chassis 12 to prevent oxidation while maintaining conductive properties needed for good chassis grounding. A variety of conductive inks may be used, such as silver or copper based conductive inks that are applied to chassis 12 with conventional techniques, such as pad printing.

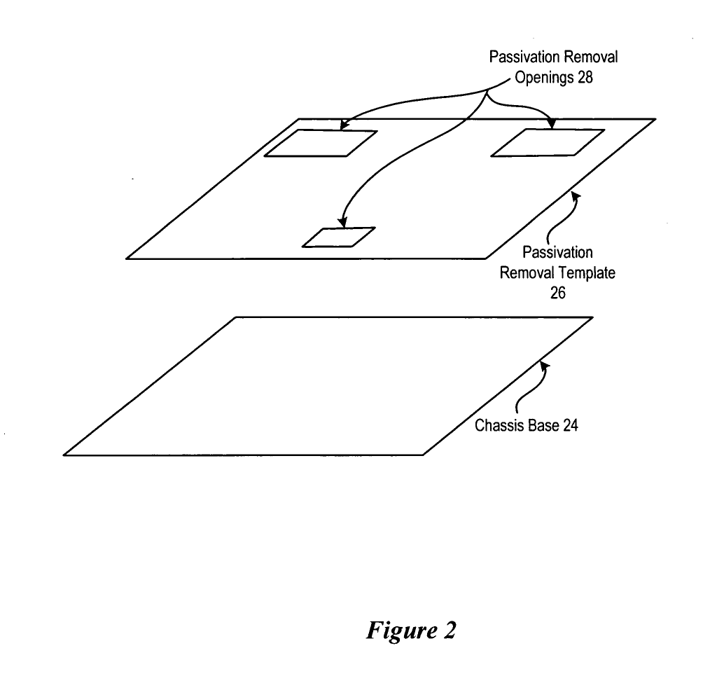

Referring now to FIG. 2, a passivation removal template 26 is depicted aligned with an information handling system chassis base 24. Information handling system chassis base 24 is, for example, die cast magnesium that is passivated by a phosphate treatment to manage oxidation for the application of paint. Chassis base 24 supports processing components, such as a motherboard, within an enclosure formed by other chassis portions. For example, after a motherboard is coupled to chassis base 24, other chassis portions, such as side and top portions, are couple to chassis base 24 to form chassis 12. Passivation removal template 26 has passivation removal openings 28 that align over chassis base 24 at the locations where a conductive surface is needed. Passivation at the surface of chassis base 24 is removed at the locations of passivation removal openings 28 so that conductive ink may be applied to an unpassivated surface of chassis base 24 that has high conductivity. For example, passivation is removed by mechanical cleaning, such as media blasting with sand or other media, grinding, milling and mechanical sanding. Application of the conductive ink protects the unpassivated surface from oxidation.

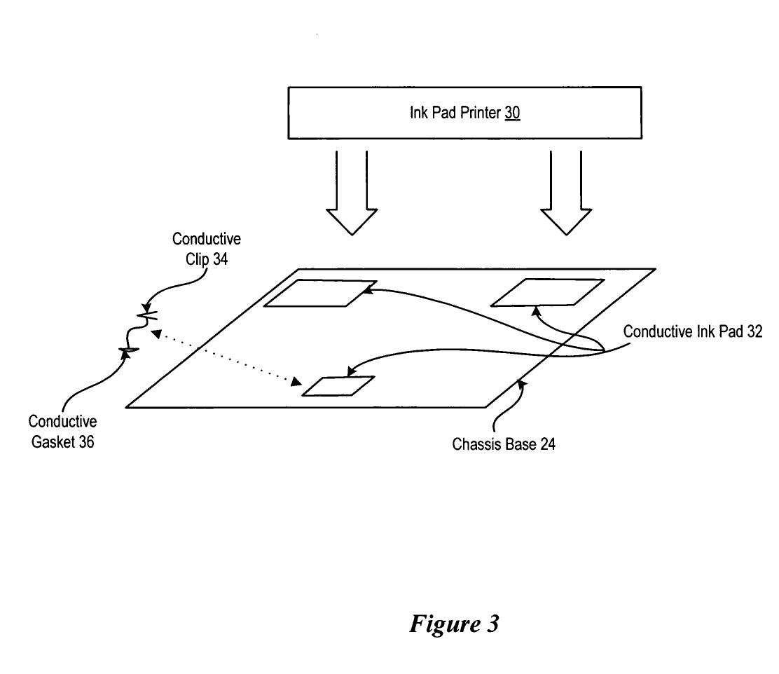

Referring now to FIG. 3, the information handling system chassis base 24 is depicted with conductive ink disposed by an ink pad printer 30. Ink pad printer 30 applies conductive ink, such as silver or carbon based inks, to the unpassivated portions of chassis base 24 so that conductive ink pads 34 are available to provide electrical communication to chassis base 24. In alternative embodiments, alternative ways of applying conductive ink may be used, such as screen printing. As an example providing electrical communication with chassis 12, a conductive clip 34 or conductive gasket 36 couple to a conductive ink pad 32 to provide an electrical contact between chassis base 24 and another object, such as a ground of a processing component or a connection to another portion of chassis 12. Interfacing all portions of chassis 12 with each other through conductive ink pads 32 and an electrical connector, such as clip 34 or gasket 36, provides effective electromagnetic shielding of components contained within chassis 12.

Although the present invention has been described in detail, it should be understood that various changes, substitutions and alterations can be made hereto without departing from the spirit and scope of the invention as defined by the appended claims.

What is claimed is:

1. An information handling system comprising:
a metallic chassis operable to support processing components;
plural processing components disposed in the metallic chassis, the processing components operable to process information; and
conductive ink disposed on at least a portion of the metallic chassis, the conductive ink operable to conduct electricity between the chassis and an electrical contact.

2. The information handling system of claim 1 wherein the metallic chassis comprise magnesium.

3. The information handling system of claim 2 wherein the magnesium is passivated except at the portion having conductive ink.

4. The information handling system of claim 1 further comprising an electrical contact interfacing the conductive ink to a ground of a processing component.

5. The information handling system of claim 4 wherein the electrical contact comprises a conductive gasket.

6. The information handling system of claim 4 wherein the electrical contact comprises a clip.

7. The information handling system of claim 1 wherein the chassis comprises first and second portions, each portion having conductive ink, the information handling system comprising an electrical contact providing electrical communication between the conductive ink of the first and second portions.

8. The information handling system of claim 1 wherein the conductive ink comprises a silver ink.

9. The information handling system of claim 1 wherein the conductive ink comprises a carbon ink.

10. A method for electrically interfacing with a metallic component, the method comprising:
passivating the metallic component;
removing the passivating at a portion of the metallic component; and
applying conductive ink at the portion to provide electrical communication with the metallic component.

11. The method of claim 10 wherein the metallic component comprises magnesium and passivating the metallic component comprises applying phosphate.

12. The method of claim 10 wherein removing the passivating further comprises grinding the portion of the metallic component.

13. The method of claim 10 wherein removing the passivating comprises milling the portion of the metallic component.

14. The method of claim 10 wherein removing the passivating comprises mechanically sanding the portion of the metallic component.

15. The method of claim 10 wherein removing the passivating comprises:
placing a template over the metallic component, the template having an opening defining the portion; and
mechanically cleaning the portion.

16. The method of claim 15 wherein mechanically cleaning comprises blasting the portion with a media.

17. An information handling system chassis comprising:
first and second metallic portions operable to couple with each other to contain processing components;
conductive ink disposed on the first and second portions; and
an electrical contact coupled to the conductive ink to provide electrical communication between the first and second portions.

18. The information handling system chassis of claim 17 wherein the metallic portions comprise magnesium.

19. The information handling system of claim 18 wherein the conductive ink comprises silver.

20. The information handling system of claim 18 wherein the conductive ink comprises carbon.
